(19) United States
(12) Patent Application Publication
(10) Pub. No.: US 2009/0152665 A1
(43) Pub. Date: Jun. 18, 2009

(54) FABRICATING METHODS OF PHOTOELECTRIC DEVICES AND PACKAGE STRUCTURES THEREOF

(75) Inventors: Wen Liang Tseng, Hsinchu City (TW); Lung Hsin Chen, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., Hsinchu County (TW)

(21) Appl. No.: 12/332,744

(22) Filed: Dec. 11, 2008

(30) Foreign Application Priority Data
Dec. 14, 2007 (TW) 096147804

(51) Int. Cl. H01L 27/00; H01L 21/00

(52) U.S. Cl. 257/461; 438/73; 257/E21.001; 257/E27.001

(57) ABSTRACT

The invention discloses a method for fabricating a photoelectric device. A ceramic substrate is first provided, and then a first patterned electrode and a second patterned electrode are formed on and underneath the surface of the ceramic substrate. A plurality of photoelectric devices is sequentially connected to the first electrode layer with a wire solder or a eutectic joint method. The encapsulation materials cover the each photoelectric die to prevent damaged from the external force or environment. Cutting the ceramic substrate along the spaces between the photoelectric dies forms a plurality of independent package units.

### BACKGROUND OF THE INVENTION

1. Field of the Invention

The present invention relates to fabricating methods of photoelectric devices and package structures thereof, and more particularly to methods and photoelectric devices using a die bonding process or a eutectic joint process to mount a photoelectric die.

2. Description of the Related Art

LEDs (light emitting diode) have advantages including small size, high illuminating efficiency and long life. They are anticipated to be the best light source for the future. Because of the rapid development of LCDs (liquid crystal display) and the trend of full-sized screen displays, white light LEDs are applied not only to indication lamps and large size screens but also to consumer electronics products (e.g., cell phones and personal digital assistants).

A package structure can be seen as the protector of a semiconductor die and an interface of signal transmission. It serves dies not only for mounting, sealing and protection, but also enhancing the conductive capability. Moreover, it is the communication bridge between the circuits inside the die and the circuits external to the package. That is the contacts of the die can be connected to the external electrodes of the package with metal wires. These electrodes can be electrically connected to the other elements through the metal wires on a printed circuit board. Therefore, the package technology is the very important part of integrated circuit products. The package of a photoelectric product will seriously affect the photoelectric transformation efficiency of the die. For example, refractive index, absorption index and the surface character of a package material will directly affect the photoelectric performance of the mounted photoelectric die.

At present, the package types of a photoelectric device are generally classed as a transistor outline (TO), an oval lamp, a square lamp, a printed circuit board (PCB) and a resin package, etc., wherein the resin package is the major package type for surface mount devices (SMDs). The TO package is utilized for testing the package of a die or a LASER diode. The oval lamp uses an egg-shaped epoxy resin to seal the lead frame comprising two electrodes. A reflection cup is formed on the end part of one electrode, wherein a photoelectric semiconductor die is mounted inside the cup. This conventional package structure comprises two pins. It is also packaged with three pins according to the circuit character of a photoelectric device. The principle of the square lamp is similar to the oval lamp. However, the square shape is formed for the package of a transparent epoxy resin. Various convex lenses can be added at the center of an upper surface for adjusting the view angle of the package. The lead frame in the square lamp comprises two electrodes. Each electrode comprises two pins so that the package structure comprises four pins. A PCB package utilizes PCB as a substrate, wherein a photoelectric semiconductor die is mounted on the PCB, and is covered with the layer of transparent epoxy resin. A lead frame is packaged as a PCB-package-like structure, wherein the extension pins of the electrodes are bent. The lead frame is usually a metal and is covered with a resin material to form the main body. A lead frame is also used for a resin package. In some embodiments, an opaque white material can be added in the resin material. The white resin is formed as a cup structure around a photoelectric die. Finally, the cup is filled with transparent epoxy resin or fluorescent powder added resin. Because different ways for bending the pin of an electrode, the resin package can be a top light emitting device or a side light emitting device.

With the miniature trend in photoelectric devices, the package mode using metal lead frame will meet the bottleneck. Because the limitation of the precision of a lead frame, the scale of the device cannot be unlimitedly miniaturized, and the reflection surface is difficultly formed. There is a problem that resin materials cannot stand a high temperature when they are used to cover the lead frame. Use of a photoelectric die packaged with resin material having emitting wave length shorter than 400 nm will speed up the degradation of the resin material. In addition, due to the resin material cannot dissipate heat well, the increasing of the temperature of the photoelectric die causes a decrease in the light emitting efficiency. Usually, a heat dissipation structure is added inside a package structure to overcome the problem.

There are some shortcomings if a PCB is as a substrate for mounting a photoelectric die in the package structure of a photoelectric device. The structure cannot bear the high temperature during the process of an IR-reflow so that the flip chip method cannot be applied. Therefore, the thickness of the package structure of a photoelectric device cannot be reduced to satisfy the trend of miniaturized devices.

In addition, if a photoelectric die or a photoelectric semiconductor die is driven with an inverse voltage or an overcharge voltage, it is easily damaged. In a dry area, static electricity from human bodies can damage a photoelectric semiconductor die. In order to increase the reliability of products, electrostatic protection measures can be adopted. A zener diode is parallelly connected to a photoelectric die as an electrostatic protection measure. If the inverse voltage is over, the zener diode is conducted. The current passing through the zener diode will not damage the photoelectric semiconductor die. At present, a zener diode and a photoelectric semiconductor die are mounted on the same plane. The emitting light or absorbed light of a photoelectric semiconductor die will be affected by a neighbor zener diode. Generally speaking, zener diodes are black. No matter what color a zener diode is, it absorbs light or reflects light and affects the performance of a photoelectric semiconductor die.

From the above, a package structure that can bear the high temperature during the process of an IR-reflow and be with better character of heat dissipation for further increasing the emitting efficiency is needed for the market.

### SUMMARY OF THE INVENTION

An aspect of the present invention is to provide fabricating methods of photoelectric devices and package structures thereof. A ceramic substrate is adhered to a photoelectric semiconductor with a flip chip method for fabricating a photoelectric device. This kind of the package structure can bear high temperature during a reflow process and has better heat dissipation characteristic.

Another aspect of the present invention is to provide the package structure of a photoelectric device wherein the photoelectric device and related electronic devices are respectively disposed on the both sides of a substrate so that the electronic devices will not affect the photoelectric device.

In view of the above aspects, the present invention discloses a fabrication method for photoelectric devices, comprising the steps of: providing a ceramic substrate; forming a first patterned electrode layer and a second patterned electrode on the two surfaces of the ceramic substrate respectively; electrically connecting a plurality of photoelectric dies to the first patterned electrode layer with a eutectic joint procedure respectively; covering the photoelectric dies with an encapsulation material; and forming a plurality of independent package units by cutting the ceramic substrate along the spaces between the photoelectric dies.

The ceramic further comprises a plurality of opening holes, and in each opening hole, a vertical conductive part is formed after forming the first patterned electrode layer and the second patterned electrode respectively.

The method further comprises a step of forming a plurality of vertical conductive parts with a silver dipping method or a barrel plating method, wherein the first patterned electrode layer is electrically connected to the second patterned electrode by the vertical conductive parts.

The ceramic substrate comprises a plurality of cutting lines so that a plurality of independent package units are formed by cutting, peeling, or snapping with a diamond knife along the cutting lines, wherein the cutting lines are formed with a LASER or a mold pressing.

A flip chip method is utilized for the eutectic joint procedure.

The encapsulation material comprises a thermoplastic or a thermosetting polymeric material, wherein the thermosetting polymeric material includes resins and silica gels.

The first patterned electrode layer and the second patterned electrode comprises a plurality of N-type electrodes and a plurality of P-type electrodes respectively.

The present invention also discloses a package structure for photoelectric devices, comprising a ceramic substrate, a first electrode layer, 15 a second electrode layer, a photoelectric die, and a plurality of vertical conductive parts. The first electrode layer and the second electrode layer are formed on the both sides of the ceramic substrate. The photoelectric die is mounted on the first electrode with a flip chip method. The plurality of vertical conductive parts is electrically connected to the first electrode layer and the second electrode layer.

The ceramic substrate comprises AlN, BeO, SiC, glass, AlO, or diamond.

The photoelectric die is a light emitting diode die.

The first electrode layer and the second electrode layer comprise at least N-type electrode and at least one P-type electrode respectively. One of the vertical conductive parts is electrically connected to the N-type electrode of the first electrode layer and the N-type of the second electrode layer, and the other one of the vertical conductive parts is electrically connected to the P-type electrode of the first electrode layer and the P-type of the second electrode layer.

The ceramic substrate further comprises a plurality of opening holes, and in each opening hole, a vertical conductive part is disposed. Or, the vertical conductive parts are disposed on the sides of the ceramic substrate.

The photoelectric die and the first electrode layer are eutectic jointed by a plurality of bumps.

The package structure of a photoelectric device of the present invention comprises a substrate, a photoelectric device and an electronic device. The substrate has at least one conductive layer to act as a single-layer circuit structure or a multi-layer circuit structure of the photoelectric die and electronic die.

The photoelectric device is mounted on the surface of the substrate. The electronic device is mounted on the other surface opposite to the surface on which the photoelectric device is mounted. The substrate may be a metal frame, a printed circuit board or a ceramic substrate, wherein the metal frame is covered with a plastic material to form the structure of a plastic lead frame chip carrier. The reflection cup formed with the plastic material reflects the light emitted from the photoelectric device mounted inside the reflection cup. At the same time, the electronic device is mounted inside the package cup formed with the plastic material. A first conductive layer and a second conductive layer are disposed on the both sides of the printed circuit board, wherein the first conductive layer is electrically connected to the second conductive layer by a silver barrel plating method or by the plurality of opening holes of the printed circuit board. The photoelectric die is a light emitting diode, a LASER diode or a photo-receiver. The electronic die is an electrostatic protection device, an electronic passive device, a diode or a transistor. The reflection cup and the package cup are filled or dispensed with the encapsulation material and are disposed on the upper and underneath surface of the substrate respectively. The reflection cup contains the photoelectric die. The package cup contains the electronic die.

In addition, the fabrication structure of a photoelectric device of the present invention can be formed with the high temperature or low temperature co-fired ceramic process. The circuit structure can comprise at least one layer of ceramic pieces, and a patterned electrode can be formed on the one-sided or both sides of the ceramic pieces with a printed or semiconductor process by design. The upper reflection cup can utilize multiple thin ceramic pieces or a thick ceramic piece to form a window or windows with a perforation step. The walls inside the reflection cup can be plated with silver or aluminum. The underneath package cup also can utilize multiple thin ceramic pieces or a thick ceramic piece as the upper reflection cup. There is a hole in the package cup. The circuit on the substrate is electrically connected to the bottom of the package cup through a conductor formed inside the hole. At the bottom of the package cup, the external patterned electrodes can be formed on the surface of a ceramic piece with a printed process or a semiconductor process, and end electrodes can be formed with a silver dipping method or a barrel plating method. The package structure with the electrodes of the invention can be mounted on a circuit board or other circuit bases by a surface mount technology.

The photoelectric die such as an LED is electrically connected to the circuit on the substrate with a wire bonding method or a flip chip method. Subsequently, an epoxy resin or silicon is filled or dispensed in the reflection cup to protect the photoelectric die in the reflection cup. An electronic die (e.g., a zener Diode for an electrostatic protection purpose) is mounted on the underneath of the substrate. This electronic die is electrically connected to the electrodes of the substrate with a wire bonding method or a flip chip method. Finally, the package cup is filled with encapsulation material. If the substrate is a printed circuit board, encapsulation materials are formed on the both sides of the substrate by using a transfer molding method. During the mounting of this package structure, the cup for emitting or receiving a light using can be mounted perpendicular or parallel to the mounting bottom base by using the external electrodes with a silver dipping method.

### BRIEF DESCRIPTION OF THE DRAWINGS

The invention will be described according to the appended drawings in which:

FIGS. 1A-1G are the diagrams illustrating the steps of the fabricating method of a photoelectric device in accordance with present invention;

FIGS. 2A-2F are the diagrams illustrating the steps of another fabricating method of a photoelectric device in accordance with present invention;

FIGS. 3-11 are the cross-sectional diagrams showing the package structure of a photoelectric device in accordance with each embodiment of the present invention; and

FIGS. 12-14 show the top view of the package structure of a photoelectric device in accordance with each embodiment of the present invention.

### PREFERRED EMBODIMENT OF THE PRESENT INVENTION

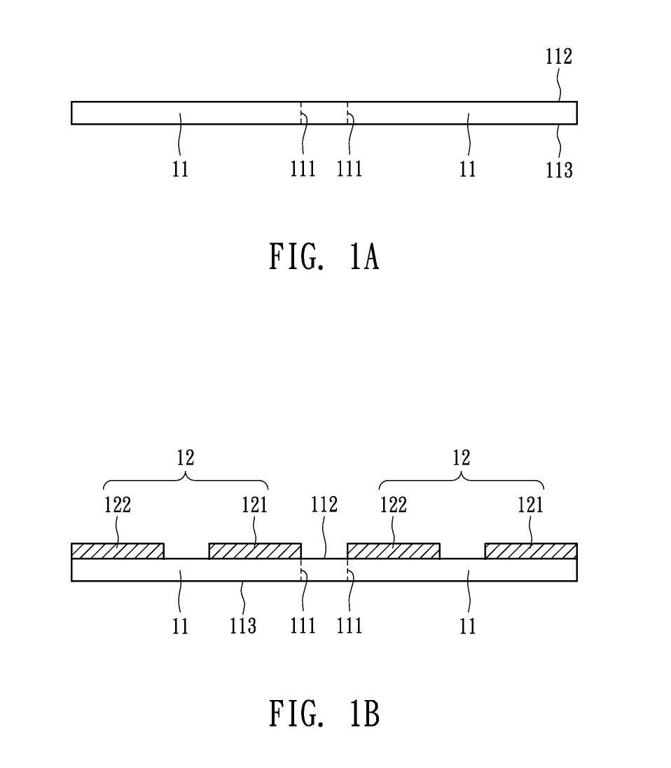

FIGS. 1A-1G are the diagrams illustrating the steps of the fabricating method of a photoelectric device in accordance with present invention. The cutting lines on the ceramic substrate 11 are formed with a LASER or a mold pressing. The most use material of the ceramic substrate is AlO. The other substitute materials comprise AlN, BeO, SiC, glass, Al, or diamond. The slurry preparation or slip preparation is the first step for making the ceramic substrate 11. The slurry is the combination of organic materials and inorganic materials, wherein a constant ratio of ceramic powder to glass powder are mixed for the inorganic materials, and organic materials comprise polymer binder, plasticizer and organic solvent, etc. The purposes of adding the glass powder into the inorganic material include adjustments of the thermal expansion character parameter of the ceramic substrate 11, adjustments of the character of a dielectric constant, and adjustments of a sintering temperature.

As shown in FIG. 1B, the first electrode layer 12 comprising a plurality of N-type electrodes 121 and a plurality of P-type electrodes is formed on the upper surface 112 of the ceramic substrate 11. The semiconductor processed for forming the first electrode layer 12 with an electrode pattern comprise following four ways:

1. A plating layer is first formed on the upper surface 112 with an evaporation method or a sputtering method, and then using an optical lithography method transfers a pattern. The etching step is used for forming the needed pattern. Finally, photo resist is removed.

2. A pattern is first transferred with optical lithography method and then a plating layer is formed on the upper surface 112 with an evaporation method or a sputtering method. Finally, photo resist is removed.

3. A plating layer is first formed on the upper surface 112 with an evaporation method or a sputtering method, and then using an optical lithography method transfers a pattern. A mask is formed with an electroplating method or a chemical plating method, and then the plating layer is removed. The etching step is used for forming the needed pattern. Finally, photo resist is removed.

4. A plating layer is first formed on the upper surface 112 with an evaporation method or a sputtering method, and then using an optical lithography method transfers a pattern. The etching step is used for forming the needed pattern and then photo resist is removed. Finally, a needed metal layer is formed with a chemical plating method.

As shown in FIG. 1C, the second electrode layer 13 is formed on the underneath surface 113 of the same ceramic substrate 11, wherein the second electrode layer 13 comprises a plurality of N-type electrode 131 and a plurality of P-type electrode 132 which are in pattern form. According to FIG. 1D, the photoelectric die 14 with the bump 15 is mounted on the first electrode layer 12 by using a flip chip method. Different bumps 15 are soldered and connected to the N-type electrodes 121 and P-type electrodes 122 respectively. The package structure using a flip chip method has shorter signal propagation path compared to the wired bonding method, so that the quality and the intensity of the signal can be conserved more completely. Therefore, the applications of the package using a flip chip method will be increasing in communication fields and electro-optical fields.

As shown in FIG. 1E, the encapsulation material 16 covers the photoelectric dies 14 to prevent damaged from the external force or environment. The thermosetting and the thermoplastic polymeric materials can be applied to molding to form the encapsulation of the encapsulation material 16. The plastics such as novolac epoxy resin or silica gel having the excellent molding characters is the major plastic molding material. However, the materials with some shortcomings will affect the reliability of the package. Because a single material could not perform the ideal character needed for molding, plastic molding material needed to be added with organic and inorganic materials for having the best character. The plastic molding material is generally composed of novolac epoxy resin, accelerator (or called kicker), curing agent (or called modifier), inorganic filler, flame retardant and mold release agent, etc. The silica gel is another option for substituting the resin related materials. It is also the packaging material for packaging electronic device. It can be applied to package structure requiring the related applications of higher temperature environment, lower temperature environment, lower absorbent, and lower dielectric. The binding strength between the oxygen and the silicon in silica gel is stronger than the binding strength between the carbons in resin related materials.

As shown in FIG. 1F, an independent package unit 10a is formed with peeling, snapping, or a diamond knife segmenting the cutting line 111 on the ceramic substrate 11, and then vertical conductive parts 17 as shown in FIG. 1G are formed with a silver dipping method or a barrel plating method. Finally, as shown in FIG. 1G, the photoelectric device 10 is mounted on the surface. The N-type electrode 121 is electrically connected to the N-type electrode 131 by the vertical conductive part 17. The P-type electrode 122 is electrically connected to the P-type electrode 132 by the vertical conductive part 17.

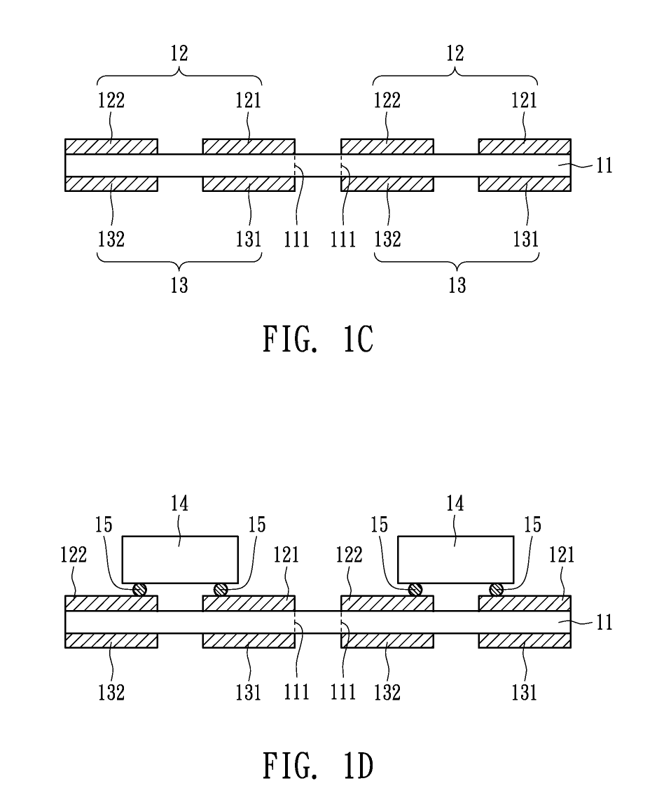

FIGS. 2A-2F are the diagrams illustrating the steps of another fabricating method of a photoelectric device in accordance with present invention. The cutting lines 211 on the ceramic substrate 21 are formed with a LASER or a mold pressing. As shown in FIG. 2A, the cutting lines 211 on the ceramic substrate 21 are formed with a LASER or a mold pressing. With the LASER, a plurality of opening holes 28 is formed on the ceramic substrate 21, as shown in FIG. 2B. A plurality of opening holes 28 also can be formed during the green step of making the ceramic substrate 21.

As shown in FIG. 2C, the first electrode layer 22 is formed on the upper surface 212 of the ceramic substrate 21. The first electrode layer 22 comprises patterns of a plurality N-type electrode 221 and a plurality P-type electrode 222. Similarly, the second electrode layer 23 is formed on the underneath surface 213 of the ceramic substrate 21. The second electrode layer 23 comprises patterns of a plurality N-type electrode 231 and a plurality P-type electrode 232. The vertical conductive parts 27 are formed in the opening holes. The N-type electrode 221 is electrically connected to the N-type electrode 231 by the vertical conductive part 27. The P-type electrode 222 is electrically connected to the P-type electrode 232 by the vertical conductive part 27.

As shown in FIG. 2D, the photoelectric die 24 with the bump 25 is mounted on the first electrode layer 22 by using a flip chip method. Different bumps 25 are soldered and connected to the N-type electrode 221 and P-type electrode 222 respectively. The encapsulation material 26 covers the photoelectric dies 24 to prevent damaged from the external force or environment, as shown in FIG. 2E.

As shown in FIG. 2F, an independent package unit 20 is formed with peeling, snapping, or a diamond knife segmenting the cutting line 211 on the ceramic substrate 21.

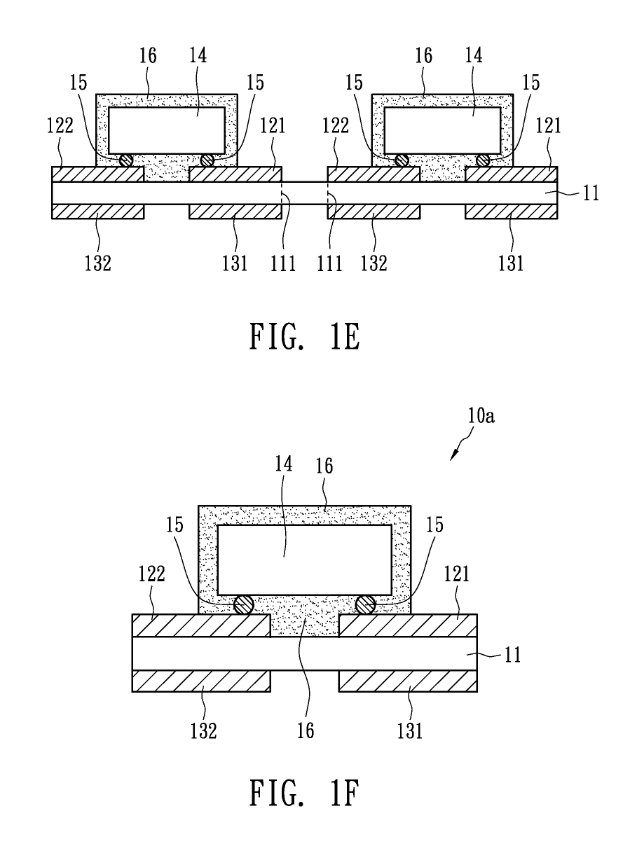

FIG. 3 is a cross-sectional diagram showing the package structure 30 in accordance with the embodiment of the present invention. The conductive layers 31, 32 are formed on the substrate 34. The photoelectric device (or photoelectric die) 33 is mounted on the substrate 34, and is electrically connected to the conductive layers 31, 32 by using a wire bonding method or a flip chip method. The electronic device (or electronic die) 35 is mounted underneath the substrate 34 and is electrically connected to the conductive layers 31, 32 by using a wire bonding method or a flip chip method. On the both sides of the substrate 34, the encapsulation material 39 is utilized to cover the photoelectric device 33 and the electronic device 35 with transfer molding method. In this exemplary embodiment, the substrate 34 can be a printed circuit board or a ceramic substrate.

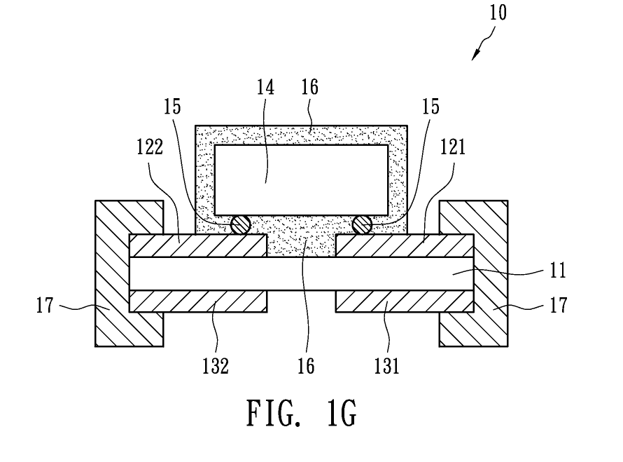

FIG. 4 is a cross-sectional diagram showing package structure 40 in accordance with another embodiment of the present invention. The difference from the structure in FIG. 3 is that conductive layers are electrically connected through the passageways in substrate. The conductive layers 31, 32 are formed on the substrate 34, wherein the conductive layers 31, 32 are electrically connected through the passageways 371, 372 on the substrate 34. The photoelectric device 33 is mounted on the substrate 34, and is electrically connected to the conductive layers 31, 32 by using a wire bonding method or a flip chip method. The electronic device 35 is mounted underneath the substrate 34 and is electrically connected to the conductive layers 31, 32 by using a wire bonding method or a flip chip method. On the both sides of the substrate 34, the encapsulation materials 39 are utilized to cover the photoelectric device 33 and the electronic device 35 with transfer molding method. In this exemplary embodiment, the substrate 34 can be a printed circuit board or a ceramic substrate.

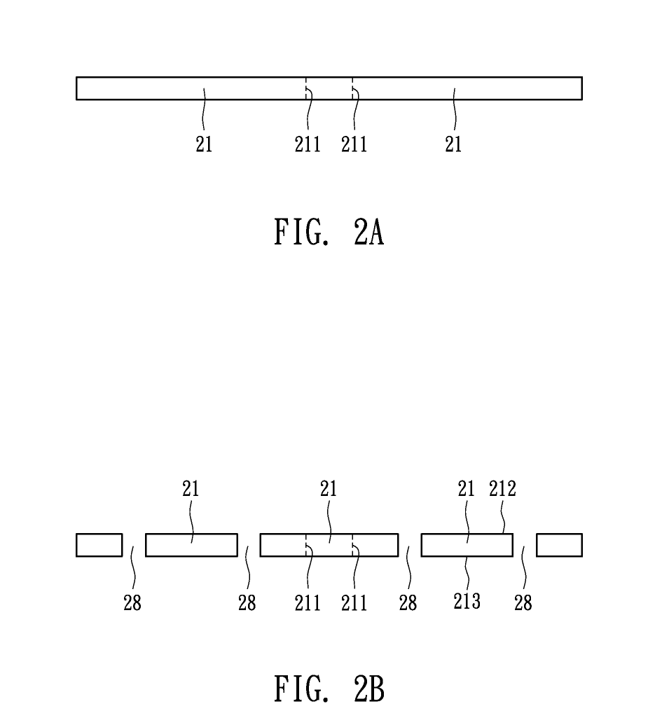

FIG. 5 is a diagram showing the package structure 50 of a photoelectric device in accordance with another embodiment of the present invention. A reflection cup 38 is added to the conventional package structure shown in FIG. 3. The reflection cup is first formed on the substrate 34, and then the conductive layers 31, 32 are formed. The photoelectric device 33 is mounted on the substrate 34, and is electrically connected to the conductive layers 31, 32 by using a wire bonding method or a flip chip method. The electronic device 35 is mounted underneath the substrate 34 and is electrically connected to the conductive layers 31, 32 by using a wire 15 bonding method or a flip chip method. Finally, the encapsulation material 39 is formed. The encapsulation material 39 can be a transparent encapsulation material. The encapsulation material 39 also can be dyed or added with phosphor such as phosphorous to change the spectrum of an emitting light. Underneath the substrate 34, the encapsulation materials 39 are utilized to cover the electronic device 35 with a transfer molding method. In this exemplary embodiment, the substrate 34 can be a printed circuit board or a ceramic substrate. The reflection cup 38 on the substrate 34 can utilize multiple thin ceramic pieces or a thick ceramic piece to form a window or windows with a perforation step.

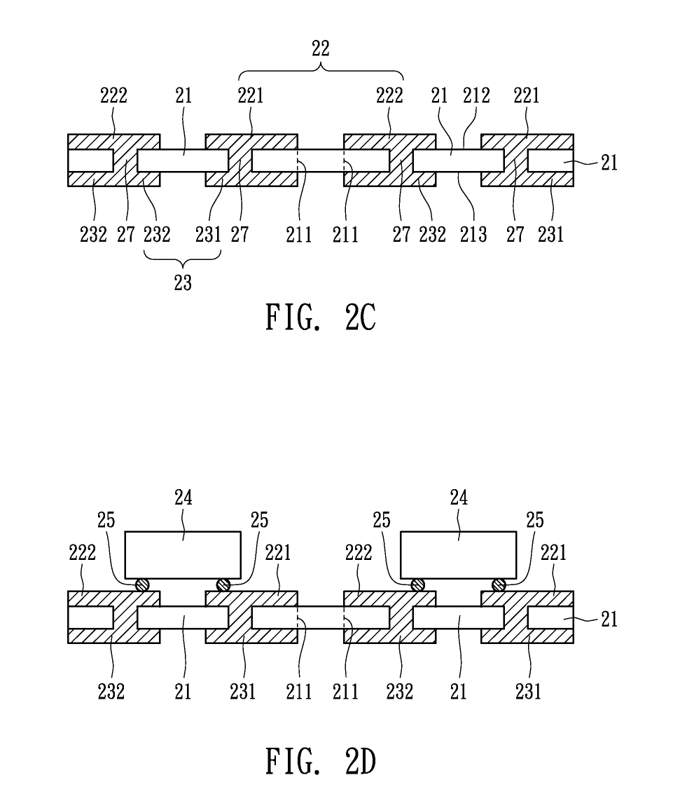

FIG. 6 is a cross-sectional diagram showing the package structure 60 of a photoelectric device in accordance with another embodiment of the present invention. The reflection cup 380 and the package cup 381 are formed on and underneath the substrate 34 respectively. The reflection layer 41 is formed on the surface of the reflection cup 380. The conductive layers 310, 311, 312, 320, 321 and 322 are formed on the substrate 34, wherein there is the insulation layer 340 between the conductive layers 310, 311, and the conductive layer 310 is electrically connected to the conductive layers 311 through the passageway 372. There is the insulation layer 341 between the conductive layers 311, 312, and the conductive layer 311 is electrically connected to the conductive layers 312 through the passageway 374. The conductive layers 320 and 321 are separated by the insulation layer 340 and electrically connected through the passageway 371. The conductive layers 321 and 322 are separated by the insulation layer 341 and electrically connected through the passageway 373. The photoelectric device 33 is mounted on the substrate 34, and is electrically connected to the conductive layers 310 and 320 by using a wire bonding method or a flip chip method. The electronic device 35 is mounted underneath the substrate 34 and is electrically connected to the conductive layers 312, 322 by using a wire bonding method or a flip chip method. The encapsulation material 390 is filled or dispensed in the reflection cup 380. The encapsulation material 391 inside the package cup 381 is used to protect the electronic device 35. The substrate 34 comprises a single-layer circuit structure or a multi-layer circuit structure. In this exemplary embodiment, the substrate 34 is composed of two insulation layers and a three-layer circuit structure. The circuits are electrically connected through the passageways 371, 372, 373, and 374 inside the insulation layers 340 and 341.

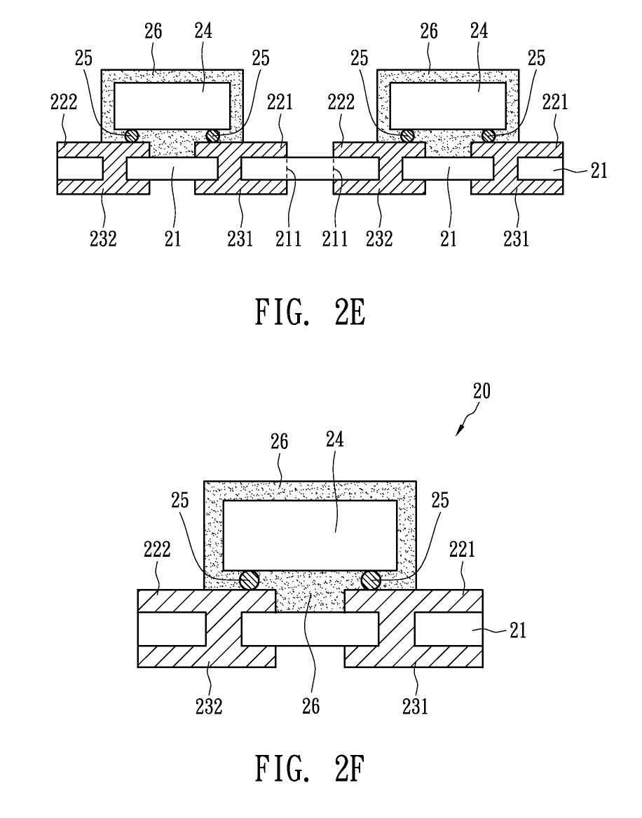

FIG. 7 is a cross-sectional diagram showing the package structure 70 of a photoelectric device in accordance with another embodiment of the present invention. The reflection cup 380 and the package cup 381 are formed on and underneath the substrate 34 respectively. The reflection layer 41 is formed on the surface of the reflection cup 380. The conductive layers 310, 311, 320 and 321 are formed on the substrate 34. The photoelectric device 33 is mounted on the substrate 34, and is electrically connected to the conductive layers 310 and 320 by using a wire bonding method or a flip chip method. The electronic device 35 is mounted underneath the substrate 34 and is electrically connected to the conductive layers 311, 321 by using a wire bonding method or a flip chip method. The encapsulation materials 390 and 391 are filled or dispensed in the reflection cup 380 and package cup 381 respectively. The external electrodes 422 and 423 are formed with a silver dipping method or a barrel plating method, wherein the external electrodes 422 and 423 are electrically connected to the conductive layer 310, 311, 320 and 321, respectively. In this exemplary embodiment, the substrate 34 is composed of an insulation layer and a two-layer circuit structure. The direction of the light of the photoelectric packaging device can be parallel or perpendicular to the surface of the installation base.

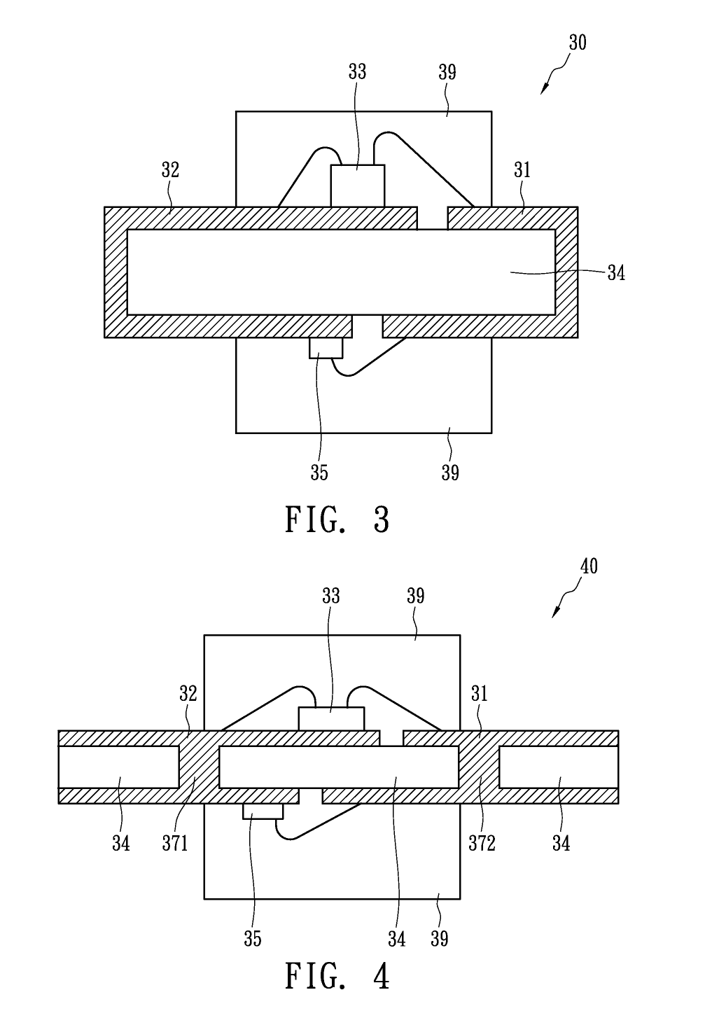

FIG. 8 is a cross-sectional diagram showing the package structure 80 of a photoelectric device in accordance with another embodiment of the present invention. The difference from the structure in FIG. 7 is that the conductive layers and the electrodes are connected through the passageway on the substrate. The reflection cup 380 and the package cup 381 are formed on and underneath the substrate 34 respectively. The reflection layer 41 is formed on the surface of the reflection cup 380. The conductive layers 310, 311, 320 and 321, are formed on the substrate 34. The conductive layers 310 and 311 are electrically connected through the passageway 372 on the substrate 34. The conductive layers 320 and 321 are electrically connected through the passageway 371 on the substrate 34. The photoelectric device 33 is mounted on the substrate 34, and is electrically connected to the conductive layers 310 and 320 by using a wire bonding method or a flip chip method. The electronic device 35 is mounted underneath the substrate 34 and is electrically connected to the conductive layers 311, 321 by using a wire bonding method or a flip chip method. Afterward, the encapsulation materials 390 and 391 are filled or dispensed in the reflection cup 380 and package cup 381 respectively. The external electrodes 422 and 423 are formed. The external electrodes 422 and 423 are electrically connected to the conductive layer 321 and 311 through the passageways 375 and 376, respectively. In this exemplary embodiment, the substrate 34 is composed of an insulation layer and a two-layer circuit structure. The direction of the light of the photoelectric packaging device is perpendicular to the surface of the installation base.

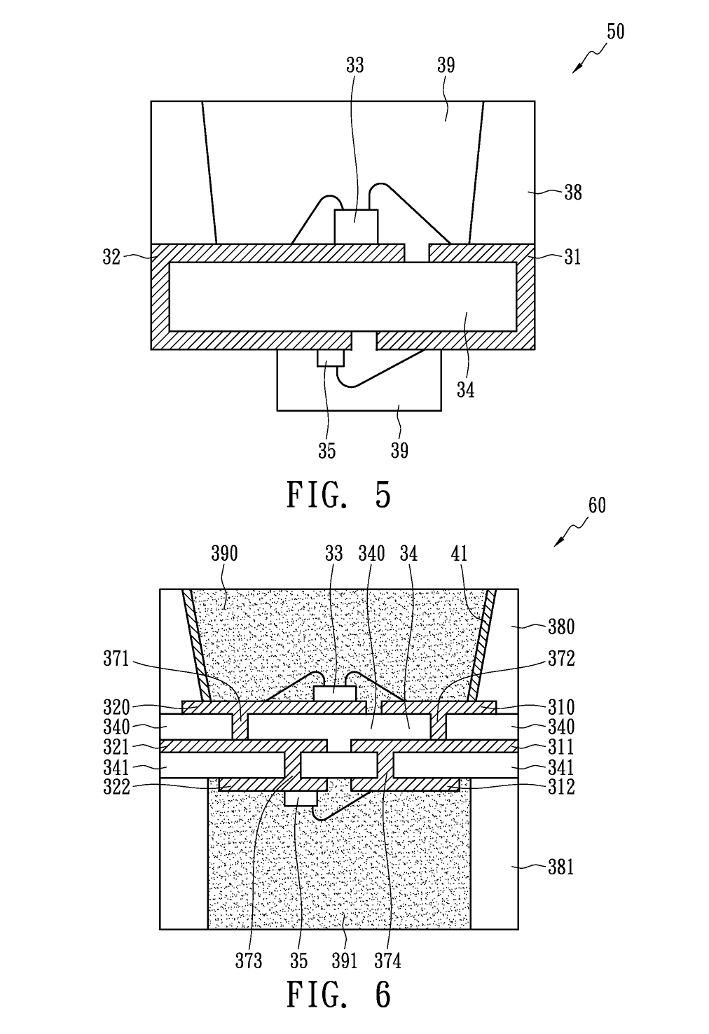

FIG. 9 is a cross-sectional diagram showing the package structure 90 of a photoelectric device in accordance with another embodiment of the present invention. The reflection cup 380 and the package cup 381 are formed on and underneath the substrate 34 respectively. The reflection layer 41 is formed on the surface of the reflection cup 380. The conductive layers 310, 311, 312, 320, 321 and 322, are formed on the substrate 34. The conductive layers 310 and 311 are electrically connected through the passageway 372 on the substrate 34. The conductive layers 320 and 321 are electrically connected through the passageway 371. The conductive layers 321 and 322 are electrically connected through the passageway 373. The photoelectric device 33 is mounted on the substrate 34, and is electrically connected to the conductive layers 310 and 320 by using a wire bonding method or a flip chip method. The electronic device 35 is mounted underneath the substrate 34 and is electrically connected to the conductive layers 312, 322 by using a wire bonding method or a flip chip method. Afterward, the encapsulation materials 390 and 391 are filled or dispensed in the reflection cup 380 and package cup 381 respectively to protect the devices. Afterward, the external electrodes 422 and 423 are formed with a silver dipping method or a barrel plating method, wherein the external electrodes 422 and 423 are electrically connected to the conductive layer 311 and 321 respectively. The substrate 34 comprises single-layer circuit structure or a multi-layer circuit structure. In this exemplary embodiment, the substrate 34 is composed of two insulation layers and three-layer circuit structures. The circuits are electrically connected through the passageways 371, 372, 373 and 374. The direction of the light of the photoelectric packaging device can be parallel or perpendicular to the surface of the installation base.

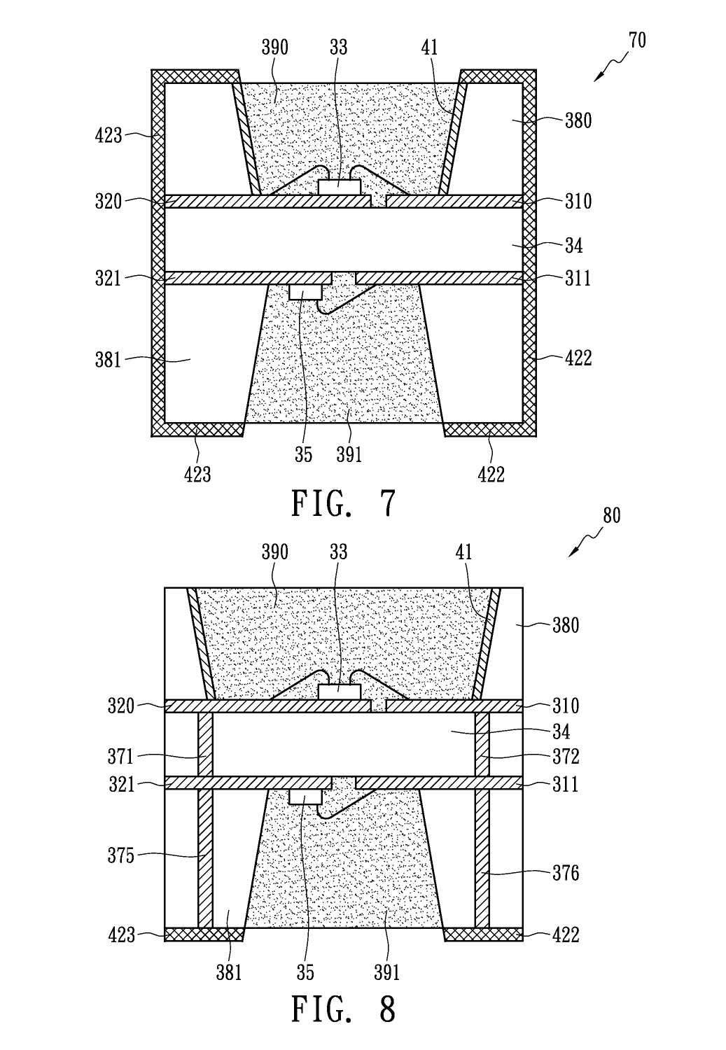

FIG. 10 is a cross-sectional diagram showing the package structure 1a of a photoelectric device in accordance with another embodiment of the present invention. The reflection cup 380 and the package cup 381 are formed on and underneath the substrate 34 respectively. The reflection layer 41 is formed on the surface of the reflection cup 380. The conductive layers 310, 311, 312, 320, 321 and 322, are formed on the substrate 34. The conductive layers 310 and 311 are electrically connected through the passageway 372 on the substrate 34. The conductive layers 311 and 312 are electrically connected through the passageway 374. The conductive layers 320 and 321 are electrically connected through the passageway 371. The conductive layers 321 and 322 are electrically connected through the passageway 373. The photoelectric device 33 is mounted on the substrate 34, and is electrically connected to the conductive layers 310 and 320 by using a wire bonding method or a flip chip method. The electronic device 35 is mounted underneath the substrate 34 and is electrically connected to the conductive layers 312, 322 by using a wire bonding method or a flip chip method. Afterward, the encapsulation materials 390 and 391 are filled or dispensed in the reflection cup 380 and package 381 respectively, to protect the devices. Finally, the external electrodes 422 and 423 are formed, wherein the external electrodes 422 and 423 are electrically connected to the conductive layer 311 and 321 through the passageways 375 and 376 on the substrate 34 respectively. The substrate 34 comprises single-layer circuit structure or multi-layer circuit structures. In this exemplary embodiment, the substrate 34 is composed of two insulation layers and three-layer circuit structures. The circuits are electrically connected through the passageways 371, 372, 373 and 374. The internal circuits are electrically connected to the external electrodes 422 and 423 through the passageway 375 and 376 in the package cup 381. The direction of the light of the photoelectric packaging device is perpendicular to the surface of the installation base.

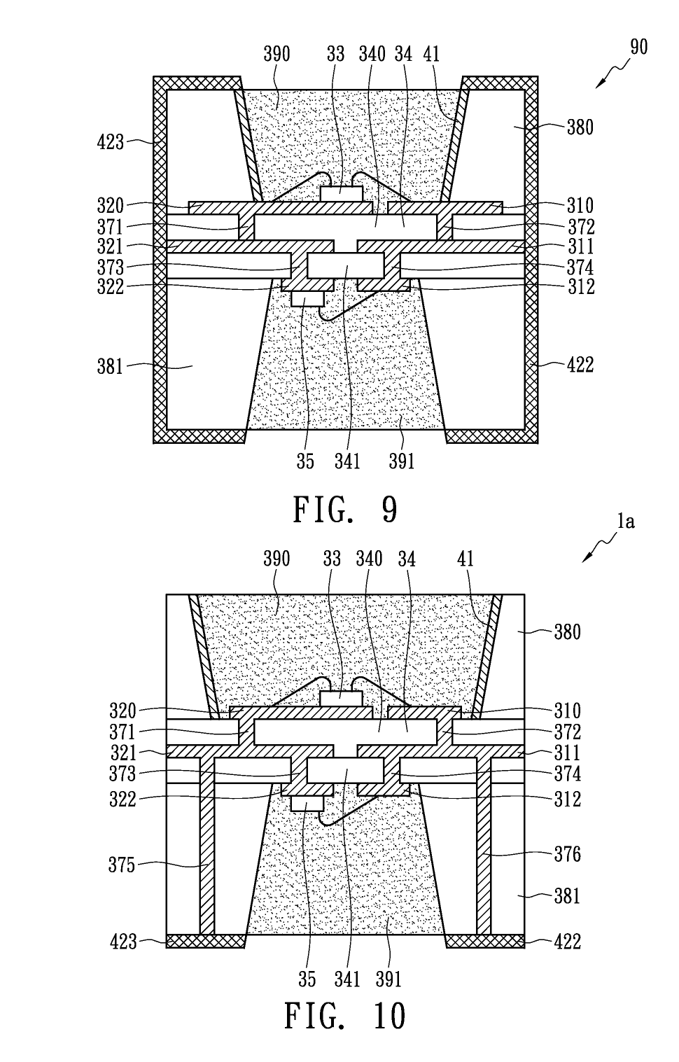

FIG. 11 is a cross-sectional diagram showing the package structure 1b of a photoelectric device in accordance with another embodiment of the present invention. The reflection cup 380 and the package cup 381 are formed on and underneath the conductive layers 31 and 32 respectively. The photoelectric device 33 is mounted on the conductive layer 32 and the electronic device 35 is mounted underneath the conductive layer 32. The encapsulation material 390 is filled or dispensed in the reflection cup 380 to protect the photoelectric device 33. The encapsulation material 391 is filled or dispensed in the package cup 381 to protect the photoelectric device 35. In more detail, the metal brackets of the conductive layers 31and 32 are covered with a plastic material to form the structure of a plastic leadframe chip carrier (PLCC). The photoelectric device 33 is mounted inside the reflection cup 380 formed with the plastic material, wherein the reflection cup 380 reflects the light emitted from the photoelectric device 33. The electronic device 35 is mounted inside the package cup 381 formed with the plastic material. A dispensing process is utilized to inject encapsulation materials 390, 391 into the reflection cup 380 and the package cup 381.

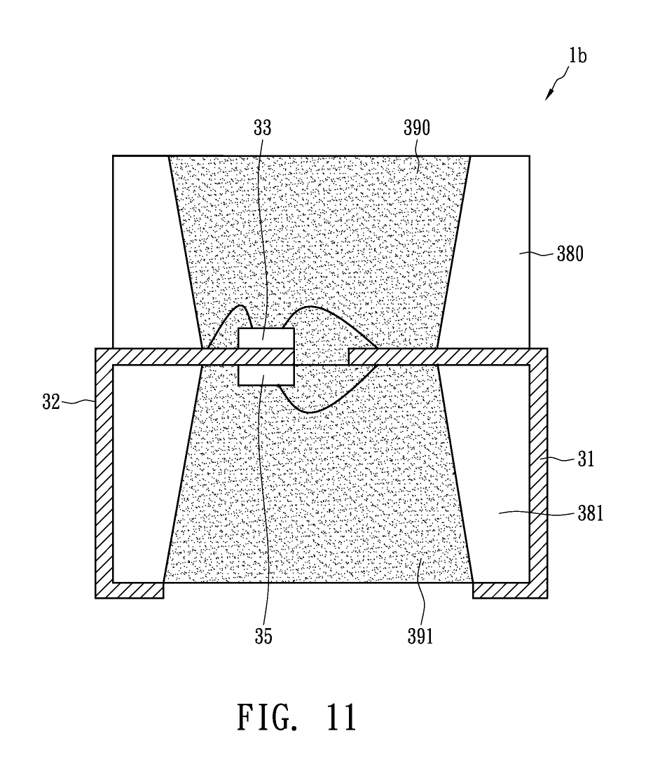

FIG. 12 shows the top view of the package structure of a photoelectric device in accordance with one embodiment of the present invention. The conductive layers 320 and 310 are formed on the substrate. The photoelectric device 33 is mounted on the conductive layer 320, and is electrically connected to the conductive layer 310 and 320 with metal wires 361 and 362 respectively. The reflection cup 380 is formed on the substrate and the package cup 381 is formed underneath the substrate (not shown). The reflection layer 41 is formed on the surface of the reflection cup 380. The insulation layer 340 of the substrate separates the reflection layer 41 and conductive layers 310 and 320. The substrate 34 comprises single-layer circuit structure or multi-layer circuit structures.

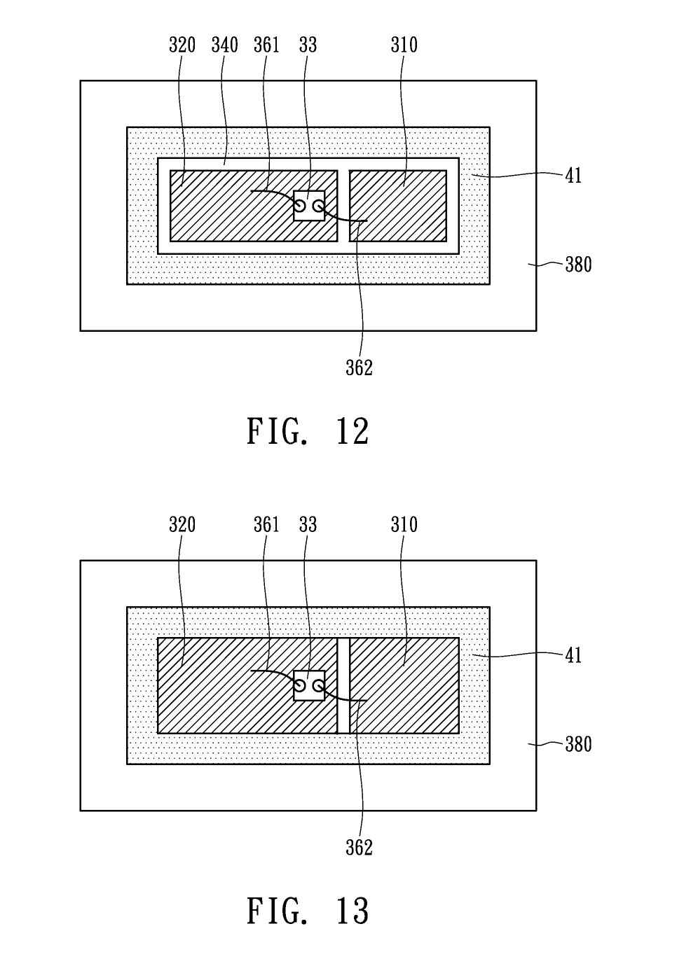

FIG. 13 shows the top view of the package structure of a photoelectric device in accordance with another embodiment of the present invention. It is similar to the FIG. 12. However, there is no insulation layer between the reflection layer 41 and conductive layers 310 and 320. The conductive layers 320 and 310 are formed on the substrate. The photoelectric device 33 is mounted on the conductive layer 320, and is electrically connected to the conductive layer 310 and 320 with metal wires 361 and 362 respectively. The reflection cup 380 is formed on the substrate and the package cup 381 is formed underneath the substrate (not shown). The reflection layer 41 is formed on the surface of the reflection cup 380. The substrate 34 comprises single-layer circuit structure or multi-layer circuit structures.

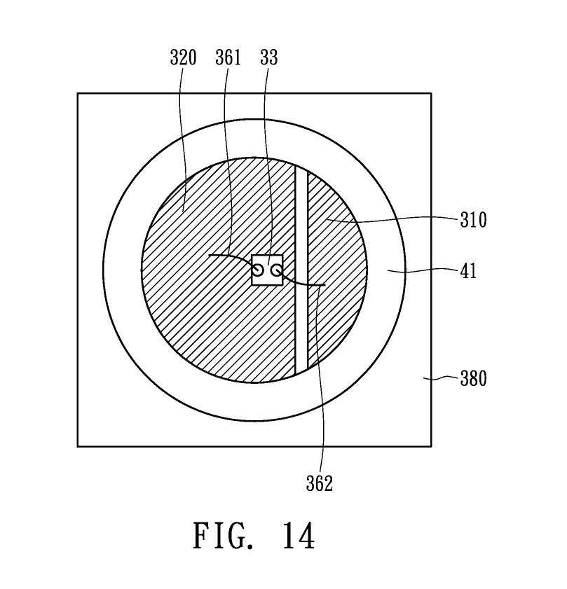

FIG. 14 shows the top view of the package structure of a photoelectric device in accordance with another embodiment of the present invention. It is similar to the FIG. 13. However, the shape is closed to square, and the open end of the reflection cup 380 is circle. The conductive layers 320 and 310 are formed on the substrate. The photoelectric device 33 is mounted on the conductive layer 320, and is electrically connected to the conductive layer 310 and 320 with metal wires 361 and 362 respectively. The reflection cup 380 is formed on the substrate and the package cup 381 is formed underneath the substrate (not shown). The reflection layer 41 is formed on the surface of the reflection cup 380. The substrate 34 comprises single-layer circuit structure or multi-layer circuit structures.

The mentioned photoelectric device can be LED or photoreceiver. The electronic device can be an electrostatic protection device (e.g. a zener diode), an electronic passive device, a diode or a transistor. The insulation layer can be a ceramic material.

In the above exemplary embodiments, the photoelectric device and the electronic device (e.g. a zener diode) of the present invention are mounted on the both sides of the substrate. Therefore, the electronic device will not obstruct the photoelectric device and not affect the emitting efficiency of the photoelectric device.

The above-described embodiments of the present invention are intended to be illustrative only. Numerous alternative embodiments may be devised by persons skilled in the art without departing from the scope of the following claims.

What is claimed is:

1. A fabrication method for photoelectric devices, comprising the steps of:
providing a ceramic substrate;
forming a first patterned electrode layer and a second patterned electrode on the two surfaces of the ceramic substrate respectively;
electrically connecting a plurality of photoelectric dies to the first patterned electrode layer with a eutectic joint procedure respectively;
covering the photoelectric dies with an encapsulation material; and
forming a plurality of independent package units by cutting the ceramic substrate along the spaces between the photoelectric dies.

2. The fabrication method of claim 1, wherein the ceramic comprises a plurality of opening holes, and a vertical conductive part is formed in each of the opening holes after forming the first patterned electrode layer and the second patterned electrode respectively.

3. The fabrication method of claim 2, further comprising a step of forming a plurality of vertical conductive parts with a silver dipping method or a barrel plating method, wherein the first patterned electrode layer electrically is connected to the second patterned electrode by the vertical conductive parts.

4. The fabrication method of claim 1, wherein the ceramic substrate comprises a plurality of cutting lines so that a plurality of independent package units are formed by cutting, peeling, or snapping with a diamond knife along the cutting lines.

5. The fabrication method of claim 4, wherein the cutting lines are formed with a LASER or a mold pressing.

6. The fabrication method of claim 1, wherein a flip chip method is utilized for the eutectic joint procedure.

7. The fabrication method of claim 1, wherein the encapsulation material comprises a thermoplastic or a thermosetting polymeric material.

8. The fabrication method of claim 7, wherein the thermosetting polymeric material includes resins and silica gels.

9. The fabrication method of claim 1, wherein the first patterned electrode layer and the second patterned electrode comprise a plurality of N-type electrodes and a plurality of P-type electrodes respectively.

10. A package structure for photoelectric device, comprising:
a ceramic substrate;
a first electrode layer disposed on the upper surface of the ceramic substrate;
a second electrode layer disposed on the underneath surface of the ceramic substrate;
a photoelectric die mounted on the first electrode layer;
an encapsulation material covering the photoelectric die; and
a plurality of vertical conductive parts electrically connected to the first electrode layer and the second electrode layer.

11. The package structure of claim 10, wherein the ceramic substrate comprises AlN, BeO, SiC, glass, Al, or diamond.

12. The package structure of claim 10, wherein the photoelectric die is a light emitting diode die.

13. The package structure of claim 10, wherein the first electrode layer and the second electrode layer comprise at least one N-type electrode and at least one P-type electrode respectively.

14. The package structure of claim 13, wherein one of the vertical conductive parts is electrically connected to the N-type electrode of the first electrode layer and the N-type electrode of the second electrode layer, and another one of the vertical conductive parts is electrically connected to the P-type electrode of the first electrode layer and the P-type electrode of the second electrode layer.

15. The package structure of claim 10, wherein the ceramic substrate further comprises a plurality of opening holes and each of the vertical conductive parts is disposed in each of the opening holes.

16. The package structure of claim 10, wherein the vertical conductive parts are disposed on the sides of the ceramic substrate.

17. The package structure of claim 10, wherein the photoelectric die and the first electrode layer are eutectic jointed by a plurality of bumps.

18. A package structure for photoelectric device, comprising:
a substrate comprising an insulation layer, wherein the material of the insulation layer is ceramic material;
a photoelectric device mounted on one surface of the substrate; and
an electronic device mounted on the other surface which is opposite to the surface on which the photoelectric device is mounted electrically coupled to the photoelectric device.

19. The package structure of claim 18, wherein the photoelectric device is a light emitting diode, a LASER diode or a photo-receiver, and the photoelectric device is mounted on the substrate by a wire bonding method or a flip chip method.

20. The package structure of claim 19, wherein the electronic device is an electrostatic protection device, an electronic passive device, a diode or a transistor, and the electronic device is mounted on the substrate by a wire bonding method or a flip chip method.
